(19) United States
(12) Patent Application Publication
(10) Pub. No.: US 2005/0243510 A1
(43) Pub. Date: Nov. 3, 2005

(54) Electronic apparatus with liquid cooling device

(76) Inventors: Kentaro Tomioka, Saitama (JP); Yukihiko Hata, Tokyo (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/070,377

(22) Filed: Mar. 2, 2005

(30) Foreign Application Priority Data
Apr. 28, 2004 (JP) P2004-134428

(51) Int. Cl. H05K 7/20

(52) U.S. Cl. 361/687

(57) ABSTRACT

According to one embodiment, an electronic apparatus comprises a housing having a bottom wall, a circuit board arranged in the housing, a heat generating element mounted on the circuit board, a heat receiving member which is thermally connected to the heat generating member, a heat radiation member which radiates heat, a pipe which is arranged between the heat receiving member and the heat radiation member, the pipe connecting to the heat receiving member at a first connection portion, and connecting to the heat radiation member at a second connection portion, and a pump which circulates a liquid coolant through the pipe. The first connection portion and the second connection portion are located between the circuit board and the bottom wall.

### CROSS-REFERENCE TO RELATED APPLICATIONS

This application is based upon and claims the benefit of priority from Japanese Patent Application No. 2004-134428, filed Apr. 28, 2004, the entire contents of which are incorporated herein by reference.

### BACKGROUND

1. Field

One embodiment of this invention relates to an electronic apparatus with a liquid cooling device for cooling heat generated inside the electronic apparatus.

2. Description of the Related Art

In recent years, electronic apparatus such as personal computers have seen outstanding improvements in processing speed. When compared with a conventional Central Processing Unit (hereinafter “CPU”) or a peripheral semiconductor element, the processing clock frequency of a CPU and that of a peripheral semiconductor element have been significantly increased in order to promote further improvement.

In connection with such performance gain, heat dissipation of the CPU and heat dissipation of other semiconductor elements has also increased. This increases the difficulty in radiating heat into the air by a heat sink thermally connected to a heat generating element, such as a CPU. As a result, there has been a development in adding liquid cooling devices to compact electronic apparatus such as personal computers. Liquid cooling devices have a higher cooling efficiency than heat radiating devices, by virtue of using, as a coolant, a liquid having higher thermal coefficient of heat transfer.

In the cooling device of liquid cooling type, a circulatory path arranged between a heat receiving member for receiving heat of the heat generating element such as a CPU, and a heat radiation member. Liquid coolant is pressurized by a pump or the like disposed at any position along the circulatory path, to thus circulate the liquid coolant.

In such a liquid cooling device, sufficient safety measures should be taken against leakage of liquid coolant.

Japanese Patent Application Publication (KOKAI) No. 2003-233441 (hereinafter “the reference”) discloses a technique pertaining to an improvement in safety against leakage of a fluid in electronic apparatus which is a compact electronic computer, having a cooling device of liquid cooling type.

In particular, the reference discloses two techniques. First, a heat receiving member and a pump, which are belonging to a cooling device, are arranged in a main body of the electronic apparatus, and a heat radiation member is arranged in a turnable panel section. A circulatory path formed from a pipe or a tube between the heat receiving member, the pump, and the heat radiation member. In the cooling device of such a structure, the heat receiving member and the pump, which are to be arranged in the main body, are located downstream of a printed circuit board to thus make an attempt to enhance safety of the printed circuit board from fluid leaks, by precluding dripping of liquid coolant on the printed circuit board.

Second, a heat receiving member, a pump, a heat radiation member, and a circulatory path, all constituting the cooling device, are arranged in a custom-designed housing differing from that of the electronic apparatus, to thus constitute a unit removably attached to the electronic apparatus. The unit is configured so as to be mechanically and thermally connected when attached to the electronic apparatus. By means of such a configuration, the entire cooling device including all circulatory paths is arranged in the unit housing separated from the electronic apparatus. Therefore, safety of the cooling device against fluid leaks is enhanced.

According to the first technique described in the reference, the heat receiving member and the pump constituting the cooling device, and the circulator path connected to the heat receiving member and the pump are arranged in a lower portion of the printed circuit board. Therefore, safety of them against fluid leaks may be enhanced.

Moreover, dispersion of the components constituting the cooling device increases the degree of freedom of layout of other electronic units, such as a printed circuit board and electronic device. Overall housing efficiency is increased, and the size of the electronic apparatus may be reduced. Therefore, the technique may be advantageous for compact electronic apparatus such as a compact electronic computer.

However, the heat receiving member constituting the cooling device, and the circulator path connected to the heat receiving member are provided in a panel section. Therefore, some measures should be taken against fluid leaks in the panel section.

Particularly, since the panel section is turnable, liquid coolant may drip on internal electronic circuits of the panel from various directions, thereby imposing limitations on measures for enhancing safety against fluid leaks.

According to the second technique described in the reference, since the entire cooling device is embodied as a unit, higher safety against fluid leaks may be achieved.

However, assembling the overall cooling device as a unit in the custom-designed housing eliminates the degree of freedom of layout of the printed circuit board and the electronic devices, both belonging to the electronic apparatus. The entire unit consisting of the cooling device and the electronic apparatus becomes bulky. Since the cooling unit is configured removably, the cooling device may be removed in a case where the electronic apparatus is to be carried during use. However, in the case, cooling capability of the cooling device drops, and hence performance of the electronic apparatus may be subjected to restrictions, such as curtailing heat by decreasing the processing capability of a CPU.

### BRIEF DESCRIPTION OF THE SEVERAL VIEWS OF THE DRAWINGS

The accompanying drawings, which are incorporated in and constitute a part of the specification, illustrate embodiments of the invention, and together with the detailed description of the embodiments given below, serve to explain the principles of the invention.

FIG. 1 is an exemplary perspective view of a portable computer according to a first embodiment of the present invention;

FIG. 2 is an exemplary perspective view from rear side of the portable computer of which a panel section is closed according to the first embodiment;

FIG. 3 is an exemplary cross-sectional view of a cooling pump in a mounted state according to the first embodiment;

FIG. 4 is an exemplary plane view of a cooling device provided in the personal computer according to the first embodiment;

FIG. 5 is an exemplary perspective view of a heat radiation member of the cooling device according to the first embodiment;

FIG. 6 is an exemplary perspective view of a radiator of the cooling device according to the first embodiment;

FIG. 7 is an exemplary perspective view of a cooling pump of the cooling device according to the first embodiment;

FIG. 8 is an exemplary cross-sectional view of the personal computer according to the first embodiment;

FIG. 9 is an exemplary cross-sectional view of a personal computer according to a second embodiment of the present invention;

FIG. 10 is an exemplary cross-sectional view of a personal computer according to a third embodiment of the present invention;

FIG. 11 is an exemplary cross-sectional view of a personal computer according to a fourth embodiment of the present invention;

FIG. 12 is an exemplary cross-sectional view of a personal computer according to a fifth embodiment of the present invention;

FIG. 13 is an exemplary cross-sectional view of a personal computer according to a sixth embodiment of the present invention; and

FIG. 14 is an exemplary cross-sectional view of a personal computer according to a seventh embodiment of the present invention.

### DETAILED DESCRIPTION

Various embodiments according to the present invention will be described hereinafter with reference to the accompanying drawings. In general, according to one embodiment of the invention, an electronic apparatus comprises a housing having a bottom wall, a circuit board arranged in the housing, a heat generating element mounted on the circuit board, a heat receiving member which is thermally connected to the heat generating member, a heat radiation member which radiates heat, a pipe which is arranged between the heat receiving member and the heat radiation member, the pipe connecting to the heat receiving member at a first connection portion, and connecting to the heat radiation member at a second connection portion, and a pump which circulates a liquid coolant through the pipe. The first connection portion and the second connection portion are located between the circuit board and the bottom wall.

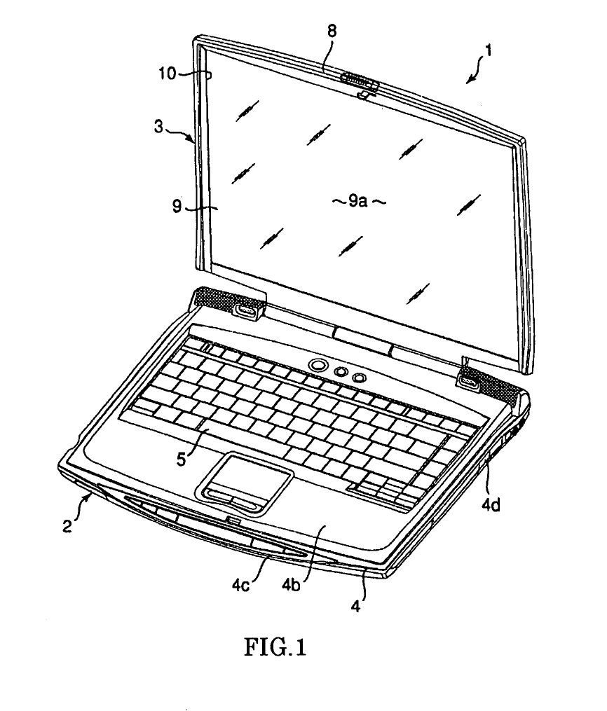

According to a first embodiment, FIG. 1 to FIG. 8 show a personal computer 1 that is one type of an electronic apparatus.

The personal computer 1 comprises a computer main body 2 and a panel section 3. The computer main body 2 has a low-profile box-shaped main body housing 4. The main body housing 4 further has a bottom wall 4a, an upper wall 4b, a front wall 4c, right and left walls 4d, and a rear wall 4e. A plurality of exhaust outlets 6 for exhaust cooling air are formed in the rear wall 4e. The upper wall 4b of the main body housing 4 supports a keyboard 5.

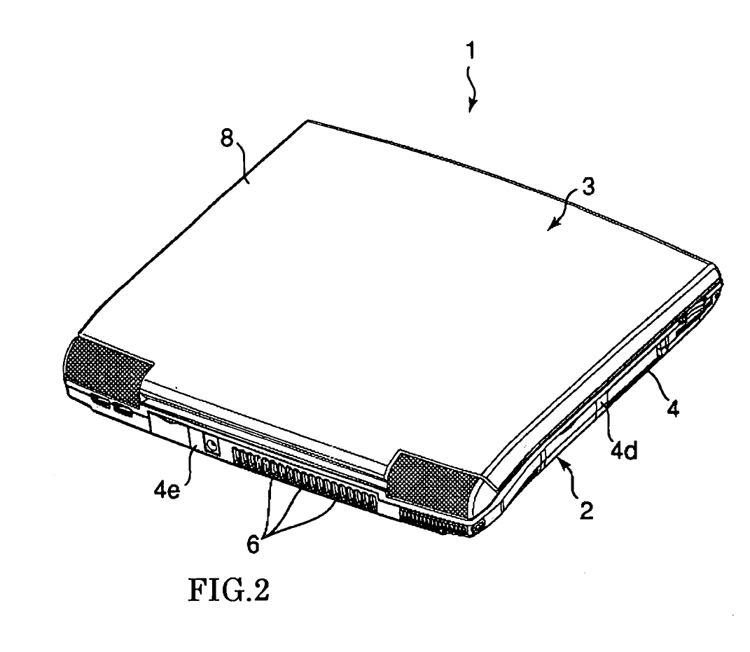

The panel section 3 has a panel section housing 8 and a display section 9. The display section 9 is housed in the panel section housing 8 and has a display panel 9a. The display panel 9a is exposed from an opening section 10 formed in the front surface of the panel section housing 8. The panel section housing 8 is turnably supported by way of a hinge provided on a rear end portion of the main body housing 4. FIG. 1 shows the appearance of the personal computer 1 when the panel section 3 is opened, and FIG. 2 shows the appearance of the same when the panel section 3 is closed.

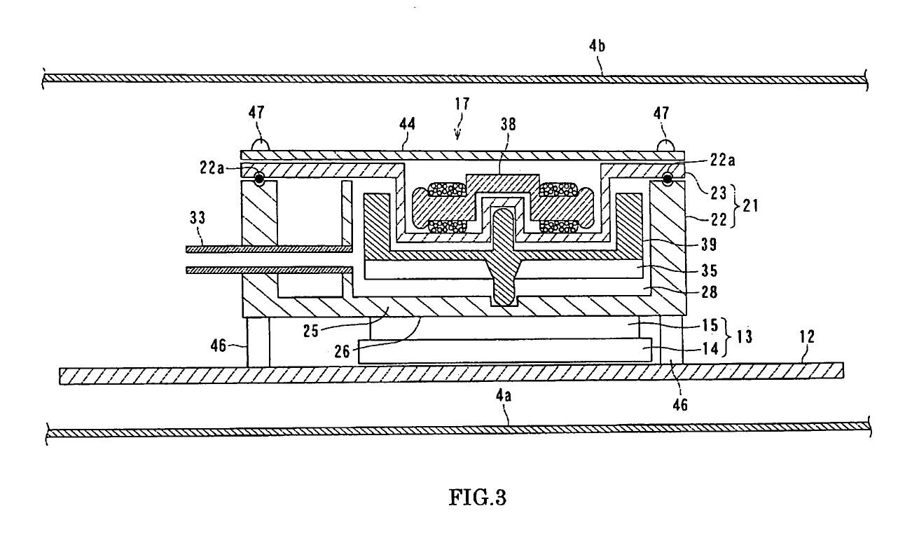

FIG. 3 shows a cross section of a printed circuit 12 to be arranged in the main body housing 4, a cross section of a semiconductor element which is a heat generating element mounted on the printed circuit board 12, such as a Central Processing Unit (hereinafter “CPU”) 13, and a cross section of a cooling pump 17 thermally connected to the CPU 13.

The printed circuit board 12 is disposed substantially in parallel with the space between the bottom wall 4a and the upper wall 4b of the main body housing. The CPU 13 may be mounted on either an upper or lower surface of the printed circuit board 12. FIG. 3 shows a cross section of the CPU 13 when the CPU 13 is mounted on the upper surface of the printed circuit board 12.

The CPU 13 has a base board 14 and a heat dissipater 15 to be provided at the center of the upper surface of the base board 14. The heat dissipater 15 dissipates heat over the surface thereof upon receipt of the heat originating from internal electronic elements of the CPU 13. Efficient cooling of the heat dissipater 15 is indispensable for maintaining operation of the CPU 13.

An exterior surface of a bottom wall 25 of the cooling pump 17 becomes a heat receiving surface 26 and is thermally connected to the surface of the heat dissipater 15. According to one embodiment of the invention, the cooling pump 17 is fastened to the printed circuit board 12 by way of a boss section 46 by causing, e.g., a fastening element 47 (e.g., screw), to penetrate through the cooling pump 17.

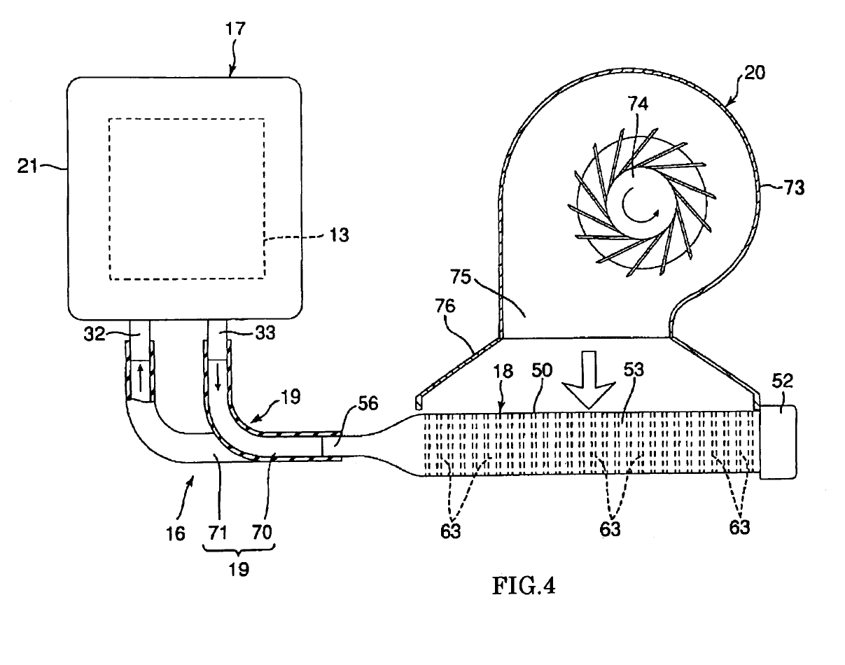

FIG. 4 shows an example structure of a cooling device 16 to be arranged in the computer main body 2.

The cooling device 16 comprises the cooling pump 17, a radiator 18, a circulatory path 19, and an electric fan 20. According to one embodiment of the invention, a “heat radiation member” constitutes the radiator 18 and the electric fan 20. The cooling pump 17 is disposed so as to cover the CPU 13 mounted on the printed circuit board 12 and is thermally connected to the CPU 13.

The cooling pump 17 is formed integrally with an inlet pipe 32 for drawing liquid coolant and an outlet pipe 33 for discharging the liquid coolant. The inlet pipe 32 and the outlet pipe 33 are formed to appropriate lengths in accordance with a mounted state of the CPU 13. The inlet pipe 32 and the outlet pipe 33 may be bent appropriately in accordance with the mounted state of the CPU 13.

The radiator 18 has a first passage section 50, a second passage section 51, and a third passage section 52 through which the liquid coolant flows.

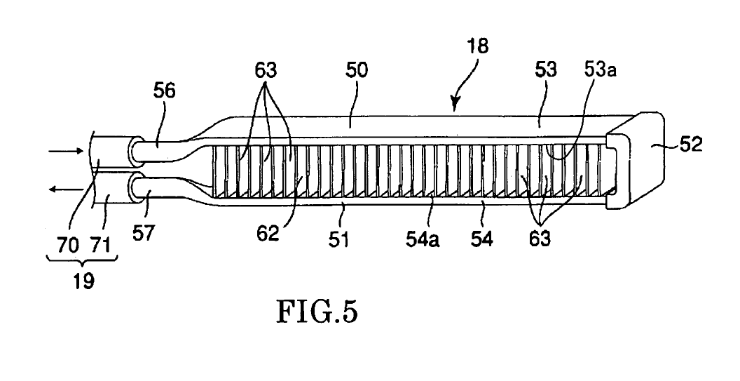

FIG. 5 shows the structure of the radiator 18 in detail. As shown in FIG. 5, the first passage section 50 has a pipe 53 having a flat cross section, and the second passage section 51 has a pipe 54 having a flat cross section. The pipes 53, 54 are arranged such that the longitudinal directions of the respective cross sections become essentially parallel to the bottom wall 4a of the main body housing 4.

The cross-sectional profile of the pipe 53 is changed to a circular shape at an upstream end of the first passage section 50, to thus form a coolant inlet 56 for allowing inflow of the liquid coolant. Meanwhile, the downstream end of the first passage section 50 is connected to the upstream end of the third passage section 52 while maintaining a flat cross sectional profile.

The cross-sectional profile of the pipe 54 is changed to a circular shape at a downstream end of the second passage section 51, to thus form a coolant outlet 57 for allowing outflow of the liquid coolant. Meanwhile, the upstream end of the second passage section 51 is connected to the downstream end of the third passage section 52 while maintaining a flat cross sectional profile.

The shape of the coolant inlet 56 of the pipe 53 and the shape of the coolant outlet 57 of the pipe 54 may be bent appropriately into, e.g., an L-lettered shape, instead.

A plurality of cooling fins 63 are provided between a support surface 53a of the pipe 53 and a support surface 54a of the pipe 54. The cooling fins 63 are fastened to the support surfaces 53a, 54a, such as by soldering for example, whereby the cooling fins 63 are in thermal communication with the pipes 53, 54. Spaces between the cooling fins 63 constitute a plurality of cooling wind passages 62.

As shown in FIG. 4, the circulatory passage 19 has an upstream pipe 70 and a downstream pipe 71.

The ends of the upstream pipe 70 are connected to the outlet pipe 33 of the cooling pump 17 and the coolant inlet 56 of the first passage section 50, respectively.

The ends of the downstream pipe 71 are connected to the inlet pipe 32 of the cooling pump 17 and the coolant outlet 57 (not shown) of the second passage 51, respectively.

The length or the degree of bend of the upstream pipe 70 and that of the downstream pipe 71 are formed appropriately in accordance with a positional relationship between the cooling pump 17 and the radiator 18.

Since the coolant pump 17 and the radiator 18 in the cooling device 16 are formed separately from each other, the length or the degree of bend of the circulator path 19 may be changed appropriately. Therefore, the cooling pump 17 and the radiator 18 may be disposed at positions where the highest packaging efficiency may be achieved, in accordance with the positional relationship between the printed circuit board 12 and the CPU 13 to be mounted thereon. Hence, the personal computer 1 may be made compact as a whole.

The electric fan 20 sends a blast of cooling air to the radiator 18. The electric fan 20 has a fan casing 73, and a fan impeller 74 housed in the fan casing 73. The fan casing 73 has a cooling wind outlet port 75 for sending cooling wind, and a wind guide duct 76 for guiding the discharged cooling wind to the radiator 18.

The structure of the cooling pump 17 will now be described in detail.

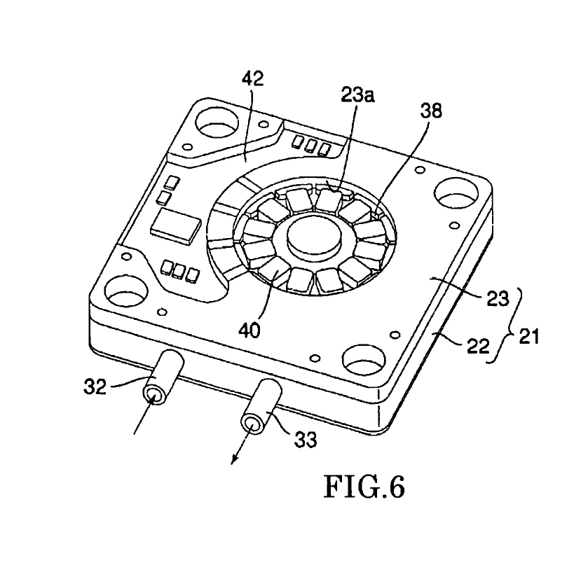

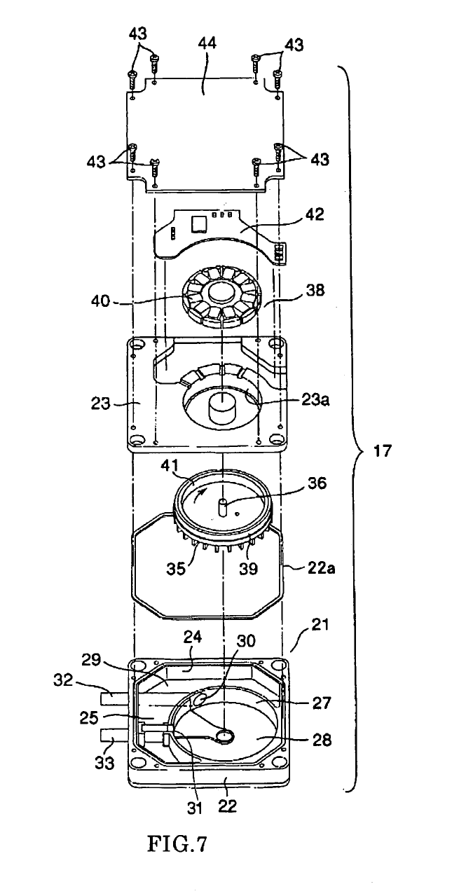

FIGS. 6 and 7 shows the structure of the cooling pump 17 according to the first embodiment of the invention, certain elements shown in the cross-sectional view of the cooling pump 17 of FIG. 3 are assigned the same reference numerals.

The cooling pump 17 comprises a pump housing 21 that serves as a heat receiving member. The pump housing 21 has a case 22 and a cover 23.

The case 22 is made of metallic material having high heat conductivity (e.g., copper or aluminum), and the cover 23 is made of resin material. The case 22 and the cover 23 are coupled together by way of an O-ring 22a. The case 22 has a recessed section 24, which opens upward in FIG. 7, and a bottom wall 25 of the recessed section 24 opposes the CPU 13. A lower surface of the bottom wall 25 serves as the heat receiving surface 26 to be brought into thermal communication with the CPU 13. In this embodiment, the O-ring 22a serves as a waterproof bonded portion that prevents leakage of the liquid coolant.

The recessed section 24 is partitioned by a partition 27 and has a pump chamber 28 and a reserve chamber 29. The reserve chamber 29 is for storing liquid coolant.

The partition 27 has an inlet port 30 and an outlet port 31. The inlet pipe 32 is connected to the inlet port 30, which draws the liquid coolant to the pump chamber 28. The outlet pipe 33 is connected to the outlet port 31, which discharges the liquid coolant from the pump chamber 28.

The pump chamber 28 houses a rotor 39. The rotor 39 is the shape of a disk, and a rotary shaft 36 is fixed to the center of the rotor 39. One end of the rotary shaft 36 is rotatably supported at the center of the pump chamber 28, and the other end of the same is rotatably supported at the center of the cover 23.

The rotor 39 has an impeller 35 for pressurizing the liquid coolant. A plurality of permanent magnets are embedded in an annular side wall 41. The impeller 35 and the plurality of permanent magnets integrally rotate around the rotary shaft 36.

The cover 23 seals, in a liquid-tight manner, the pump chamber 28 and the reserve chamber 29 where the rotor 39 is housed.

A stator 38 is housed in a recessed section 23a formed in an upper surface of the cover 23 in FIG. 7. The stator 38 has a plurality of electromagnets 40.

A predetermined electric current is applied to the plurality of electromagnets 40, whereby a rotational magnetic field develops in the stator 38. The stator 38 causes torque to arise in the rotor 39 by means of repulsive force stemming from the rotational magnetic field and a magnetic field of the permanent magnets embedded in the rotor 39, to thus rotate the rotor 39. Further, the liquid coolant is pressurized and circulated by the impeller 35 provided on the rotor 39.

A control circuit board 42 for controlling the electric current applied to the electromagnets 40 is also housed in the cover 23.

A cover 44 covers and protecting the stator 38 and the control circuit board 42, and is fastened to the pump housing 21 by fastening elements 43 (e.g., screws, rivets, etc.).

By reference to FIGS. 3 and 4, operation of the cooling pump 17 of the present invention and operation of the cooling device 16 equipped with the cooling pump 17 will now be described.

The heat dissipater 15 of the CPU 13 that is a heat generating element is thermally connected to the exterior surface 26, which is a heat receiving surface, of the bottom wall 25 of the pump housing 21 through heat-conductive grease or a heat-conductive sheet (not shown). The heat generated by the CPU 13 is transmitted to an interior surface of the pump chamber 28 by way of the bottom wall 25.

The cooled liquid coolant flows into the pump chamber 28 from the inlet pipe 32 by way of the inlet port 30. The heat of the CPU 13 transmitted to the interior surface of the pump chamber 38 is transmitted to the cooled liquid coolant. Consequently, the liquid coolant receives heat.

In the pump chamber 38, the rotor 39 rotates upon receipt of torque by means of a rotational magnetic field developing in the stator 38. By means of rotation of the impeller 35 provided on the rotor 39, the liquid coolant having received heat is pressurized and discharged from the outlet pipe 33 by way of the outlet port 31.

As shown in FIG. 4, after the liquid coolant, which received heat, has been pressurized by the cooling pump 17, the liquid coolant is discharged from the outlet pipe 33 and flows into the radiator 18 through the upstream pipe 70 of the circulatory path 19.

In the radiator 18, the liquid coolant circulates through the first passage section 50, the third passage section 52, and the second passage section 51. During the course of circulation, the heat which the liquid coolant has received from the CPU 13 is transmitted to the radiating fins 63 thermally connected to both the first passage section 50 and the second passage section 51.

The cooling wind generated by rotation of the fan impeller 74 of the electric fan 20 impinges on the first and second passage sections 50, 51 and the radiating fins 63, thereby depriving them of heat. Subsequently, the cooling wind is discharged from the plurality of exhaust outlets 6 formed in the rear wall 4e of the main body housing 4.

The liquid coolant having received the heat is cooled while being circulated through the radiator 18 in the manner mentioned above. After having passed through the downstream pipe 71 of the circulatory path 19, the cooled liquid coolant returns to the pump chamber 28 from the inlet pipe 32 of the cooling pump 17.

Through repetition of the above cycle, the heat generated in the CPU 13 is sequentially discharged to the outside of the main body housing 4 by the cooling wind generated by the electric fan 20.

In the personal computer 1 having the liquid-cooling device 16, ensuring safety against leakage of the liquid coolant circulating through the cooling device 16 is considered. If the leaked liquid coolant has adhered to electric circuits of the printed circuit board or the like, the coolant will be responsible for a failure in the electronic circuits. Therefore, in addition to providing the cooling device 16 with measures against liquid leaks, the overall personal computer 1 is provided with measures against liquid leakage as well as the cooling device 16.

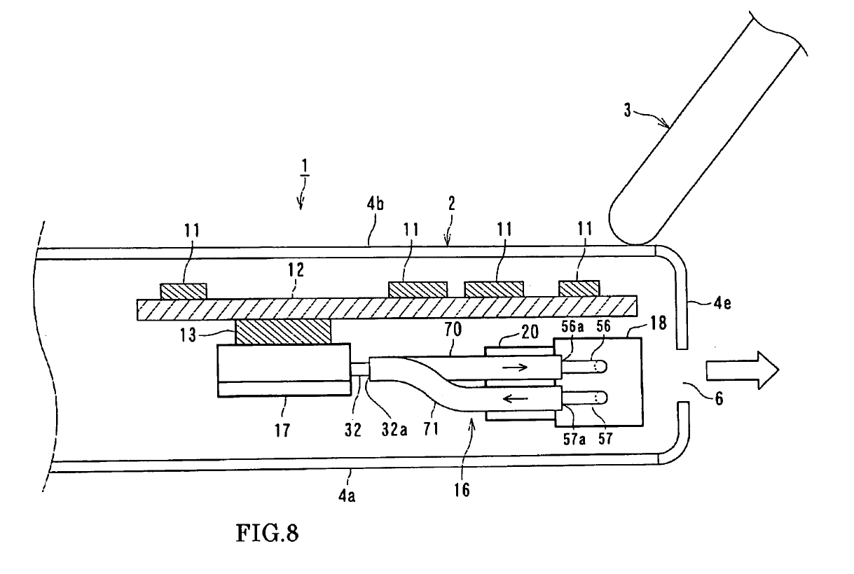

FIG. 8 shows the personal computer 1 when the panel section 3 thereof is opened; i.e., a cross section of the personal computer 1 when viewed from the right wall 4d.

The printed circuit board 12 is arranged between the upper wall 4b and the bottom wall 4a of the personal computer 1. The electronic components 11, which generate a comparatively small quantity of heat and does not require forced cooling, is mounted on the upper surface of the printed circuit board 12. The CPU 13, which generates a large quantity of heat and requires forced cooling, is mounted on a lower surface of the printed circuit board 12.

The cooling device 16 is arranged between the printed circuit board 12 and the bottom wall 4a of the personal computer 1.

The cooling pump 17 of the cooling device 16 is disposed so as to cover the CPU 13, and is connected to the printed circuit board 12 by means of an appropriate coupling member (not shown) and in thermal connection with the CPU 13.

The inlet pipe 32 of the cooling pump 17 is connected to the downstream pipe 71 by means of a pump intake connection portion 32a. Similarly, the outlet pipe 33 of the cooling pump 17, which is hidden by the inlet pipe 32 but is shown in FIG. 6, is connected to the upstream pipe 70 by means of a pump discharge connection portion 33a.

The upstream pipe 70 is connected to the coolant inlet 56 for the radiator 18 of the cooling device 16 by means of a radiator intake connection portion 56a. Similarly, the downstream pipe 71 is connected to the coolant outlet 57 of the radiator 18 by means of a radiator outlet connection portion 57a.

The radiator 18 is disposed in the vicinity of the exhaust ports 6 formed in the rear wall 4b of the personal computer 1. The cooling wind generated by the electric fan 20 is discharged to the outside of the personal computer 1 by way of the exhaust ports 6 after passing through the cooling wind passage 62 of the radiator 18.

According to the first embodiment, all of the areas where the liquid coolant circulates are located between the printed circuit board 12 and the bottom wall 4a of the personal computer 1. Consequently, even when liquid leaks have arisen in the cooling device 16, the liquid coolant drips solely to the bottom wall 4a, and does not affect the printed circuit board 12 having the electronic components 11 mounted thereon.

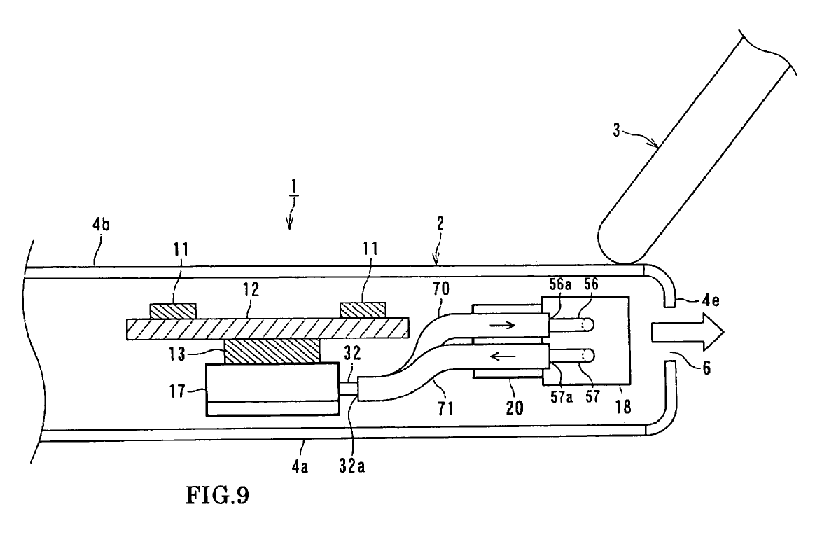

FIG. 9 shows a second embodiment of the personal computer 1.

Depending on the layout of the printed circuit board 12 arranged in the personal computer 1, there may exist areas where the printed circuit board 12 is not present between the upper wall 4b and the bottom wall 4a of the personal computer 1.

In the second embodiment, the radiator 18 and the electric fan 20 are arranged in such absent areas. In the second embodiment, the area where the liquid coolant circulates is set between the printed circuit board 12 and the bottom wall 4a or between the upper wall 4b and the bottom wall 4a in the area where the printed circuit board 12 is not present.

Therefore, as in the case of the first embodiment, even when liquid leaks have arisen in the cooling device 16, the liquid coolant drips solely to the bottom wall 4a, and does not affect the printed circuit board 12 having the electronic components mounted thereon.

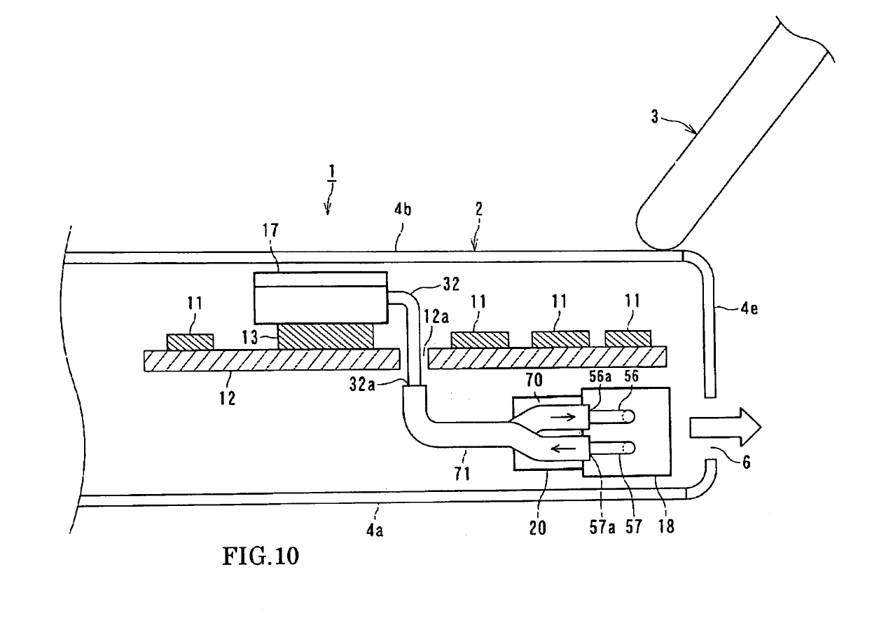

FIG. 10 shows a third embodiment of the personal computer 1.

In contrast with the first and second embodiments, in the third embodiment, the CPU 13 is mounted on the upper surface of the printed circuit board 12. Accordingly, the cooling pump 17 thermally connected to the CPU 13 is arranged on the upper surface of the printed circuit board 12.

The inlet pipe 32 and the outlet pipe 33, which are formed integrally with the cooling pump 17, are formed into essentially the shape of the letter L and are connected to the upstream pipe 70 and the downstream pipe 71 between the printed circuit board 12 and the bottom wall 4a by way of a through one or more holes 12a formed in the printed circuit board 12.

Areas of the liquid coolant circulatory path where liquid leaks are most likely to arise are as follows: the pump discharge connection portion 32a where the inlet pipe 32 and the downstream pipe 71 are connected; the pump intake connection portion 33a where the outlet pipe 33 and the upstream pipe 70 are connected; the radiator intake connection portion 56a where the coolant inlet 56 and the upstream pipe 70 are connected; and the radiator outlet connection portion 57a where the coolant outlet 57 and the downstream pipe 71 are connected.

In the third embodiment, both of the pump discharge connection portion 32a and the pump intake connection portion 33a serve as a first connection portion. In other words, the upstream pipe 70 and the downstream pipe 71, and the inlet pipe 32 and the outlet pipe 33 of the cooling pump 17 which has the heat receiving member formed therein, are connected with each other respectively, these connecting portion are the first connection.

Also, both of the radiator intake connection portion 56a and the radiator outlet connection portion 57a serve as a second connection portion. In other words, the upstream pipe 70 and the downstream pipe 71, and the coolant inlet 56 and the coolant outlet 57 of cooling pump 17 which is the heat radiation member, are connected with each other respectively, these connecting portion are the second connection.

In the third embodiment, all of these four connection portions are arranged between the printed circuit board 12 and the bottom wall 4a.

Accordingly, even when the CPU 13, which requires a cooling component, is mounted on the upper surface of the printed circuit board 12, the liquid coolant drips solely to the bottom wall 4a even when liquid leaks have arisen in the cooling device 16, as in the case of the first and second embodiments, and poses no influence on the printed circuit board 12 having electronic components mounted thereon.

As a modification of the third embodiment, the radiator 18 and the electric fan 20 may be disposed between the printed circuit board 12 and the upper wall 4b. In the case, an advantage which is the same as that obtained in the third embodiment will be obtained if the pipe of the coolant inlet 56 and that of the coolant outlet 57, which are formed integrally with the radiator 18, are made longer so as to penetrate through the printed circuit board 12, and if the radiator intake connection portion 56a and the radiator discharge connection portion 57a are interposed between the printed circuit board 12 and the bottom wall 4a.

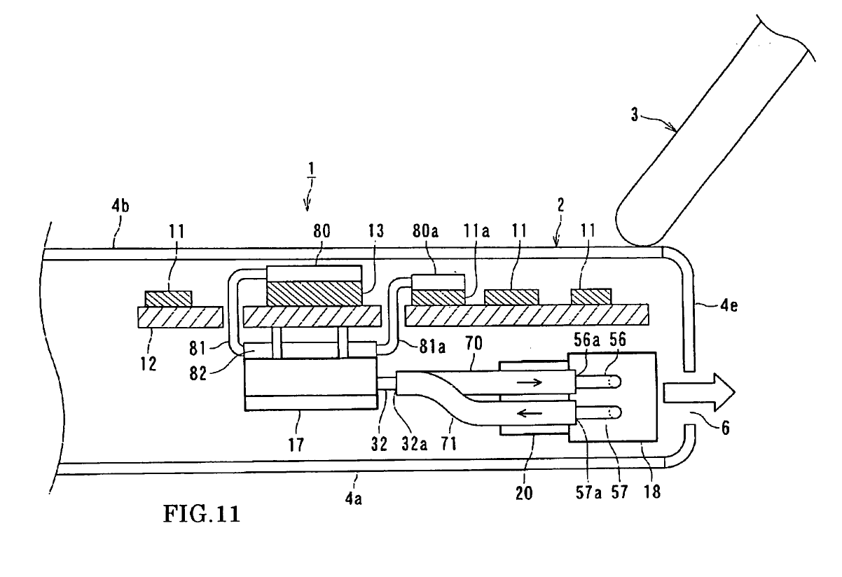

FIG. 11 shows a fourth embodiment of the personal computer 1.

In the fourth embodiment, the cooling device 16 including the cooling pump 17 is arranged between the printed circuit board 12 and the bottom wall 4a, and the CPU 13, which requires a cooling component, is mounted on the upper surface of the printed circuit board 12.

A heat receiving member 80 is thermally connected to the CPU 13, and the cooling pump 17 is simultaneously thermal connected to a heat receiving member 82. Furthermore, the heat receiving members 80 and 82 are connected together by means of, e.g., a heat pipe 81. According to this configuration, the heat generated in the CPU 13 is transmitted to the cooling pump 17 through the heat receiving member 80, the heat pipe 81, the heat receiving member 82, and cooled by the radiator 18.

The heat receiving members 80, 82 are formed from metal having high thermal conductivity, such as copper or aluminum.

As shown in FIG. 11, the heat generated in another electronic component 11a may be transmitted to the heat receiving member 82 of the cooling pump 17 by way of a heat receiving member 80a and a heat pipe 81a. In the case that the cooling device 16 has high cooling capacity, a plurality of electronic components may be cooled by means of such a configuration.

In the fourth embodiment, the heat receiving members 80, 80a serve as a first heat receiving member that abuts on the heat generating element (the CPU 13 and the electronic component 11a), the heat receiving member 82 serves as a second heat receiving member that abuts on the pump (the cooling pump 17), and the heat pipes 81, 81a serve as a heat transferring member that transfers heat from the first heat receiving member to the second heat receiving member.

According to the fourth embodiment, there may be obtained the same advantages as those obtained in the first through third embodiments while the electronic components, including the CPU 13, are mounted on the upper surface of the printed circuit board 12.

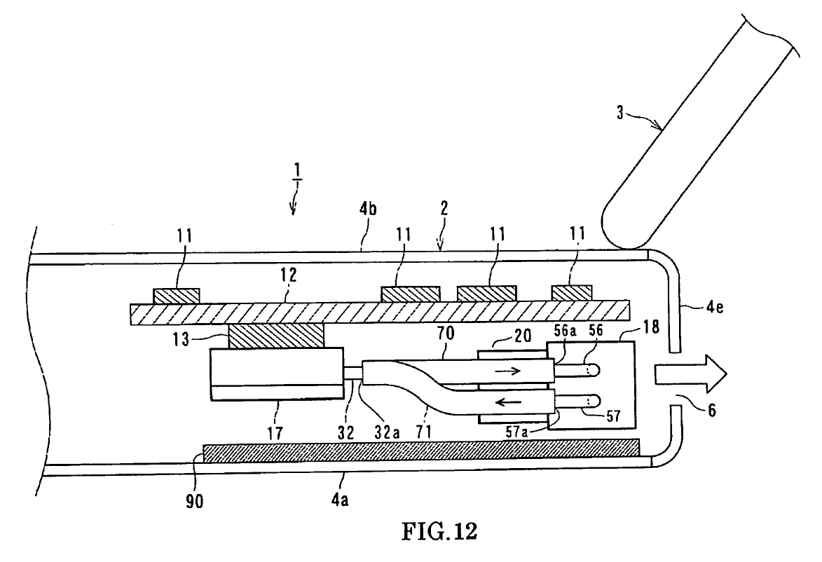

FIG. 12 shows a fifth embodiment of the personal computer 1.

In addition to the teachings provided by the first four embodiments, the personal computer as shown further comprises a bottom wall water absorptive member 90 provided between the cooling device 16 and the bottom wall 4a.

The bottom wall water absorptive member 90 is formed from a material having moisture absorptive, water-holding characteristics; e.g., water-absorptive polymer. The bottom wall water absorptive member 90 is fixed to the bottom wall 4a by means of an appropriate adhesive or a double-sided adhesive tape. The thickness of the bottom wall water absorptive member 90 is configured to be such in a range from 1 mm to 5 mm, depending on water-absorbing property, quantity of the coolant in the cooling device 16, and/or space inside the personal computer 1.

The fifth embodiment may eliminate the influence of the liquid leaks to the printed circuit board 12 and enables the bottom wall water absorptive member 90 to absorb the liquid coolant even when the liquid coolant has dropped to the bottom wall 4a.

Consequently, even when, e.g., the personal computer 1, is carried in an arbitrary attitude, leaked liquid coolant does not flow along the bottom wall 4a. Thus, an electronic component arranged around the bottom wall 4a; e.g., a hard disk drive, may reduce affection by the leaks, and hence safety against liquid leakage is enhanced.

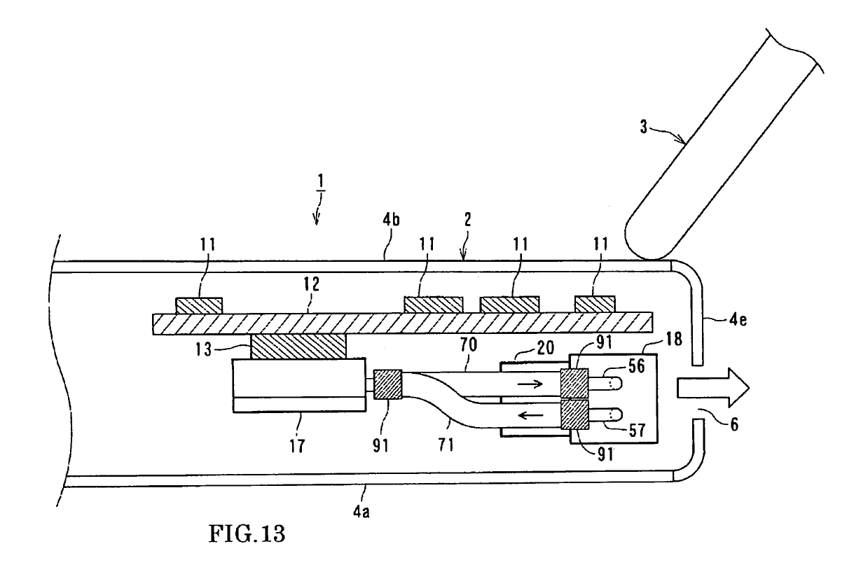

FIG. 13 shows a sixth embodiment of the personal computer 1.

In addition to the teachings provided by the first four embodiments, the personal computer further comprises a connection portion water absorptive member 91 which covers surroundings of respective connection portions; that is, the pump intake connection portion 32a, the pump discharge connection portion 33a, the radiator intake connection portion 56a, and the radiator outlet connection portion 57a.

The connection portion water absorptive member 91 is also formed from, e.g., water-absorptive polymer, as well as in the case of the bottom wall water absorptive member 90 of FIG. 12. The connection portion water absorptive member 91 is bonded to the respective connection portions by means of, e.g., an appropriate adhesive or the like.

The sixth embodiment may absorb leaked liquid before it reaches to somewhere in the personal computer 1, including the printed circuit board 12, and prevent leaks of liquid coolant to the bottom wall 4a, as well as in the case of the fifth embodiment. When compared with the fifth embodiment, a comparatively smaller quantity of water absorptive member is sufficient.

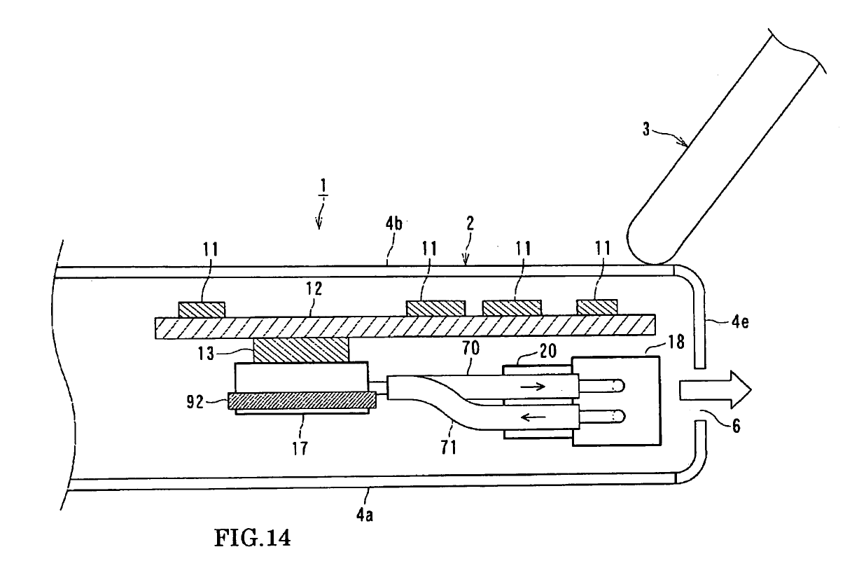

FIG. 14 shows a seventh embodiment of the personal computer 1.

As shown in FIG. 3 or 7, the case 22 and the cover 23 are sealed to the pump housing 21 of the cooling pump 17 in a fluid-tight manner by way of the O-ring 22a.

The seventh embodiment is directed toward enhancing safety against liquid leaks from the pump housing 21 by covering the periphery of a bonded portion between the case 22 and the cover 23 with a pump water absorptive member 92. For instance, water-absorptive polymer which is the same as that employed in the fifth and sixth embodiments is used as the pump water absorptive member 92.

According to the seventh embodiment, in case of occurrence of liquid leakage from the bonded portion of the cooling pump 17, the liquid coolant may be absorbed by the pump water absorptive member 92. Hence, the risk of dropping of the liquid coolant to the printed circuit board 12 or the bottom wall 4a may be prevented.

In the fifth through seventh embodiments, three types of water absorptive members; that is, the bottom wall water absorptive member 90, the connection portion water absorptive member 91, and the pump water absorptive member 92, are provided independently. However, there may also be adopted an embodiment where all of these water absorptive members are provided simultaneously. Alternatively, there may be adopted an embodiment where any two of the three types of water absorptive members may be provided.

There may also be adopted an embodiment realized by any arbitrary combination of the first through fourth embodiments, all relating to the layout of the cooling device 16, with the fifth to seventh embodiments relating to the layout of the water absorptive member.

In the foregoing embodiments, the pump constitutes the heat receiving member thermally connected to the CPU. However, the heat receiving member to be in thermal connection with the CPU may be configured separately from the pump, and the pump may be arranged at an intermediate position along the circulatory path of the liquid coolant.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. An electronic apparatus, comprising:
a housing having a bottom wall;
a circuit board implemented within the housing;
a heat generating element mounted on the circuit board;
a heat receiving member thermally coupled to the heat generating member;
a heat radiation member to radiate heat;
a pipe positioned between the heat receiving member and the heat radiation member, the pipe connecting to the heat receiving member at a first connection portion, and connecting to the heat radiation member at a second connection portion; and
a pump which circulates a liquid coolant through the pipe,
wherein the first connection portion and the second connection portion are located between the circuit board and the bottom wall.

2. An electronic apparatus according to claim 1, wherein the heat receiving member is formed as a part of the pump.

3. An electronic apparatus according to claim 1, wherein the pump and the heat receiving member are integrally provided.

4. An electronic apparatus according to claim 3, wherein the pump includes a pump housing operating as the heat receiving member.

5. An electronic apparatus according to claim 1, wherein the heat receiving element includes a first heat receiving member in contact with the heat generating element, a second heat receiving member in contact with the pump, and heat transferring member to transfer heat from the first heat receiving member to the second heat receiving member.

6. An electronic apparatus according to claim 5, wherein the housing includes an upper wall elevated above the bottom wall, the first heat receiving member is arranged between the upper wall and the circuit board, and the second heat receiving member and the pump are arranged between the circuit board and the bottom wall.

7. An electronic apparatus according to claim 1, wherein the pump is arranged between the circuit board and the bottom wall.

8. An electronic apparatus according to claim 1, wherein the heat radiation member is arranged between the circuit board the bottom wall.

9. An electronic apparatus according to claim 1, further comprising a plurality of heat generating elements each mounted on the circuit board, wherein the heat receiving member is thermally connected to more than one of the heat generating elements.

10. An electronic apparatus according to claim 1, wherein the heat radiation member comprises a radiator including fins, and a fan to direct air to the fins.

11. An electronic apparatus according to claim 10, wherein the pump and the radiator are arranged between the circuit board and the bottom wall.

12. An electronic apparatus according to claim 1, wherein the heat generating element is mounted on a surface of the circuit board facing the bottom wall.

13. An electronic apparatus according to claim 1, further comprising a water absorptive member arranged between the first connection portion and the bottom wall and between the second connection portion and the bottom wall.

14. An electronic apparatus according to claim 1, further comprising a water absorptive member arranged around an outer periphery of the first connection portion and around an outer periphery of the second connection portion.

15. An electronic apparatus according to claim 1, wherein the pump has a waterproof bonded portion that prevents leakage of the liquid coolant.

16. An electronic apparatus according to claim 15, further comprising a water absorptive member arranged around an outer periphery of the water proof bonded portion.

17. An electronic apparatus, comprising:
a housing having a bottom wall;
a semiconductor element mounted on a circuit board;
a heat receiving member thermally coupled to the semiconductor element;
a heat radiation member;
a pipe implemented between the heat receiving member and the heat radiation member, the pipe being coupled to (i) the heat receiving member at a first connector portion being located between the circuit board and the bottom wall, and (ii) the heat radiation member at a second connection portion located between the circuit board and the bottom wall; and
a pump including a pump housing, the pump to circulate a liquid coolant through the heat receiving member, the pipe, and the heat radiation member.

18. An electronic apparatus according to claim 17, wherein the heat receiving member is a surface of the housing.

19. An electronic apparatus, comprising:
a semiconductor element mounted on a circuit board;
a heat receiving member thermally coupled to the semiconductor element;
a heat radiation member;
a pipe coupled to the heat receiving member and the heat radiation member, the pipe located below the circuit board and including a first connector coupled to the heat receiving member and a second connector coupled to the heat radiation member located below the circuit board; and
a pump to circulate a liquid coolant through the heat receiving member, the pipe, and the heat radiation member.

20. An electronic apparatus according to claim 19, wherein the pump is located below the circuit board.
